(19) United States
(12) Patent Application Publication
(10) Pub. No.: US 2006/0093051 A1
(43) Pub. Date: May 4, 2006

(54) Method and device for resisting DC interference of an OFDM system

(75) Inventor: Wen-Sheng Hou, Hsin Chu (TW)

Correspondence Address: TROXELL LAW OFFICE PLLC;SUITE 1404, 5205 LEESBURG PIKE, FALLS CHURCH, VA, 22041, US

(73) Assignee: Silicon Integrated Systems Corp.

(21) Appl. No.: 10/979,208

(22) Filed: Nov. 3, 2004

(51) Int. Cl. H04K 1/10; H03D 1/04

(52) U.S. Cl. 375/260; 375/346

(57) ABSTRACT

A method and device for resisting DC interference of an orthogonal frequency division multiplexing (OFDM) system are used to obtain interference of a DC source to an OFDM system corresponding to various modulation types and frequency offsets for producing a weighting look-up table when the OFDM makes simulation. Different weights are then given to interfered sub-carriers based on this weighting look-up table when decoding. Reliable signals can thus be used to compensate interfered unreliable signals to accomplish the object of resisting DC interference for the OFDM system.

### BACKGROUND OF THE INVENTION

1. Field of the invention

The present invention relates to a method and device for resisting DC interference of an OFDM system and, more particularly, to a method and device giving different weighting offsets to different modulation types and frequency shifts to accomplish the object of resisting DC interference.

2. Description of Related Art

Orthogonal frequency division multiplexing (OFDM) can be viewed as a modulation technique, and can also be viewed as a multiplexing technique. The OFDM is a multi-carrier transmission way. It sends a string of data through a low transmission rate sub-carrier. One key to using the OFDM is to enhance the capability for resisting frequency selective fading or narrowband interference. Due to the progress in digital signal processing (DSP) and very large scale integration (VLSI) technology, the OFDM has been widely applied in high-speed digital communication technique like digital broadcasting, digital television and wireless local area network (wireless LAN). The OFDM has become an inevitable technique in future wireless and multimedia communication technology.

The OFDM technique adopts a discontinuous multi-tone technique to merge a large number of signals in carriers of different frequencies into a single signal for signal transmission. The OFDM technique has been developed for enhancing the use efficiency of spectrum or for improving the modulation of multi-carrier. It is characterized in that its sub-carriers are mutually orthogonal. The spectrum after spread spectrum and modulation can thus overlap one another, hence reducing mutual interference between sub-carriers and accomplishing various kinds of reliable high-speed data transmission.

During signal transmission of wireless communication, it is necessary for the sending end to use a carrier for modulating the baseband signal to a specified band for transmission. A carrier of the same frequency is then used at the receiving end to demodulate the signal into the baseband signal. Because it is impossible that the oscillators at the sending end and the receiving end are totally identical, there will be a frequency offset effect at the receiving end. This frequency offset will make a DC interference source interfere sub-carrier signals near the DC interference source to deteriorate the system performance. It is thus very important to solve this DC interference problem for an OFDM system.

FIG. 1 is an architecture diagram of a conventional OFDM receiving end. An OFDM signal is received by an RF module of the receiving end and then converted into a baseband signal, which is sampled by an analog-to-digital converter (ADC) and then transformed from the time domain to the frequency domain by a discrete Fourier transform (DFT) circuit. Next, the frequency domain signal is compensated for channel distortion by an equalization circuit and finally decoded by a decoder for output.

In the disclosure of U.S. Pat. No. 6,487,253 “OFDM channel estimation in the presence of interference,” a plurality of training symbols is used to estimate the channel response of the OFDM system. During operation of this OFDM system, a training symbol acquisition unit 206 is used to receive training symbols in the signal. After estimation of the interference to this signal by a channel estimation unit 207, an equalization unit 204 is used to calibrate signal data in the frequency domain. A decoding unit 205 is finally used for decoding after the calibration.

Although the interference in the RF signal has been compensated or calibrated in the prior art, the DC interference effect to the signal in the RF component is not taken into account. The present invention can get a weighting look-up table corresponding to various modulation types like BPSK, QPSK, 16-QAM, and 64-QAM and frequency offsets during simulation of an OFDM system and then give different weights to sub-carriers interfered by the DC source at the decoding unit to accomplish the object of resisting DC interference for the OFDM system.

### SUMMARY OF THE INVENTION

The present invention provides a method and device for resisting DC interference of an OFDM system. In one method, a high-pass filter can be used at the receiving end to filter out DC interference sources. The high-pass filter, however, will damage sub-carriers near the DC source. In another method, a DC remover is used to remove the DC interference source. That is, the DC interference at the receiving end is first estimated, and the DC interference is then removed based on this estimation. Although this method can reduce the number of damaged sub-carriers, there is an error of DC interference estimation. Especially when the system has frequency offset, the error of DC interference estimation is much larger. In other words, there is still residual DC source to interfere sub-carriers near the DC source after removal of DC by the DC remover. Therefore, it is necessary to a more effective method to resist the DC interference source for enhancing the performance of an OFDM communication system.

Because frequency offset will let some sub-carriers of an OFDM system be interfered by DC source, a weighting look-up table can be made corresponding to various modulation types like BPSK, QPSK, 16-QAM, and 64-QAM and frequency offsets so that the decoding unit can give different weights to interfered sub-carriers when decoding to accomplish the object of resisting DC interference for the OFDM system.

A method for resisting DC interference of the present invention comprises the steps of: receiving an OFDM signal by using an RF module; demodulating the OFDM signal by using a demodulation circuit; introducing in a weighting look-up table; and a decoding unit giving different weights to interfered sub-carriers according to a modulation type and a frequency offset by looking up said weighting look-up table.

The above weighting look-up table is made beforehand by a method comprising the steps of: generating a plurality of multi-carrier test symbols by using said RF module in the OFDM system; and receiving the test symbols of the OFDM system by using an RF module at a receiving end having DC interference source; and producing the weighting look-up table based on modulation type of the signal and the frequency offset to achieve a smaller package error rate at the receiving end.

A device for resisting DC interference according to an embodiment of the present invention comprises: an RF module for receiving an OFDM signal via a communication channel; a demodulation circuit electrically connected with the RF module; a frequency offset estimation unit electrically connected with the demodulation circuit for getting an estimated frequency offset for the OFDM signal and then obtaining a weighting look-up table based on the correspondence between the frequency offset and a modulation type; and a decoder electrically connected with the demodulation circuit for giving different weights to interfered sub-carriers according to the weighting look-up table and then decoding for output.

The various objects and advantages of the present invention will be more readily understood from the following detailed description when read in conjunction with the appended drawing, in which:

### BRIEF DESCRIPTION OF THE DRAWINGS

FIG. 1 is a system architecture diagram of an OFDM channel frequency estimation method in the interference process described in U.S. Pat. No. 6,487,253;

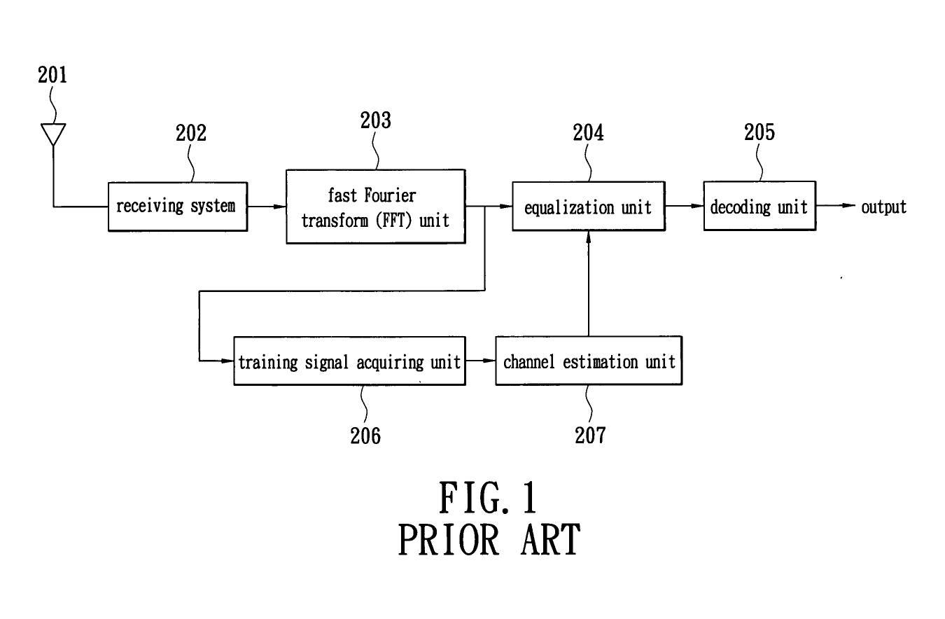

FIGS. 2A to 2C are diagrams showing the base-band signal and the frequency offset;

FIG. 3 is an architecture diagram of an OFDM system of the present invention;

FIG. 4 is a diagram showing the DC estimation and compensation before operation of an OFDM system according to a preferred embodiment of the present invention;

FIG. 5 is a flowchart of producing a weighting look-up table in a method for resisting DC interference of the present invention; and

FIG. 6 is a flowchart of a method for resisting DC interference of an OFDM system of the present invention.

### DETAILED DESCRIPTION OF THE PREFERRED EMBODIMENTS

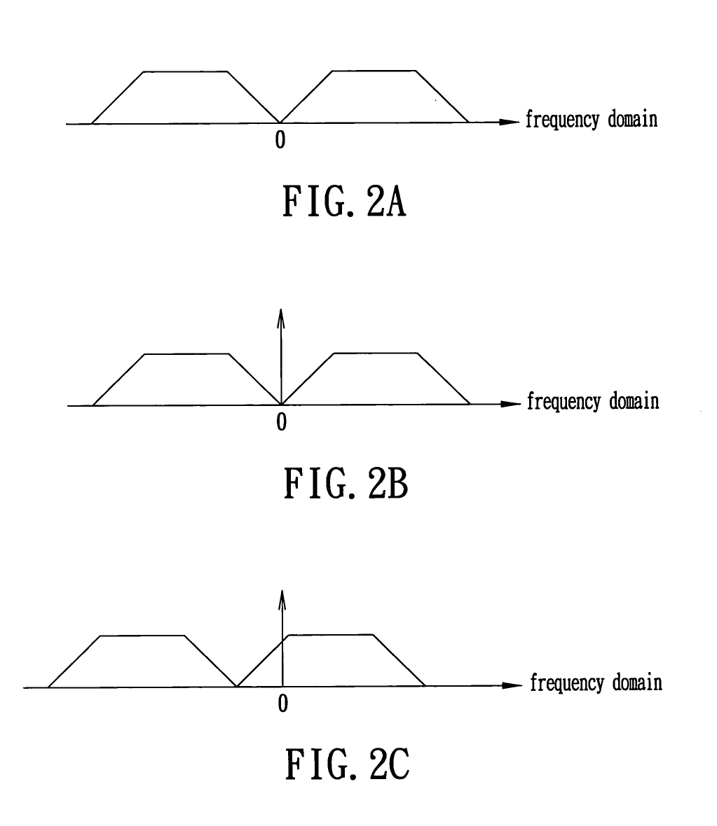

In an OFDM system, interference, especially the DC source interference in an RF component, will occur during signal transmission due to the environment or component factor. As shown in FIG. 2A, if there is no frequency offset phenomenon during demodulation at the sending end, the spectrum of the received baseband signal will show as in FIG. 2B. A DC interference source will interfere DC sub-carriers of the OFDM system. Because the DC sub-carriers of a general OFDM system is vacant sub-carriers without carrying any signal, this DC interfere source won't interfere the OFDM system. If there is frequency offset phenomenon due to different oscillation frequencies between the sending end and the receiving end of the OFDM system during demodulation, the spectrum of the received baseband signal will show as in FIG. 2C. The DC interference source will interfere some sub-carriers carrying signal of the OFDM system according to the magnitude of the frequency offset, hence causing errors and deviations in decoding of the OFDM system. The present invention makes use of a weighting look-up table built beforehand to give different weights according to different frequency offsets so that reliable information can protect unreliable information at the decoding end, hence accomplishing the object of resisting DC interference source.

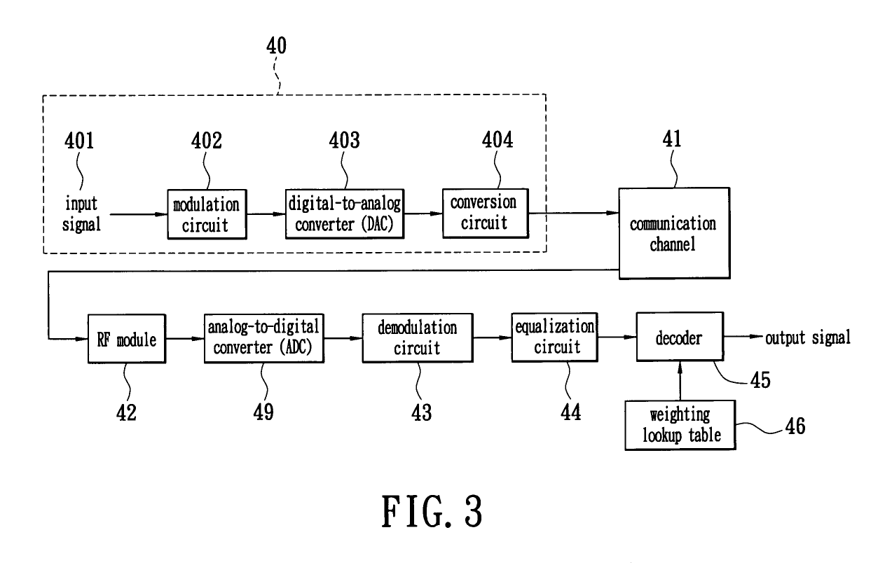

As shown in FIG. 3, an OFDM system can be divided into a signal sending end, a signal receiving end, and a channel between them. A sending end 40 has an input signal 401, which is filtered by a modulation circuit 402. The modulation circuit 402 transforms a frequency domain signal into a time domain signal by means of the inverse discrete Fourier transform (IDFT). A digital-to-analog converter (DAC) 403 then converts the digital signal into an analog signal.

Next, the analog signal is sent out by an RF module 404 at the sending end 40 via a channel 41 (e.g., the medium of air). After received by an RF module 42 of an OFDM receiver, the signal is sent to an internal circuit of the receiving end. After converted by an analog-to-digital converter (ADC) 49, a demodulation circuit 43 performs discrete Fourier transform (DFT) to the signal. The signal is then sent to an equalization circuit 44 to make compensation of channel distortion to each sub-carrier. Finally, the signal is decoded by a decoder 45 to get an output signal. In the present invention, a DC remover can first be used to remove most of the DC interference source and compensate the frequency offset at the receiving end. Next, a weighting look-up table 46 is designed to give different weights to interfered sub-carriers in accordance with modulation type and frequency offset when the decoder 45 decodes the signal. In other words, small weights are given to interfered sub-carriers so that reliable information can protect unreliable information.

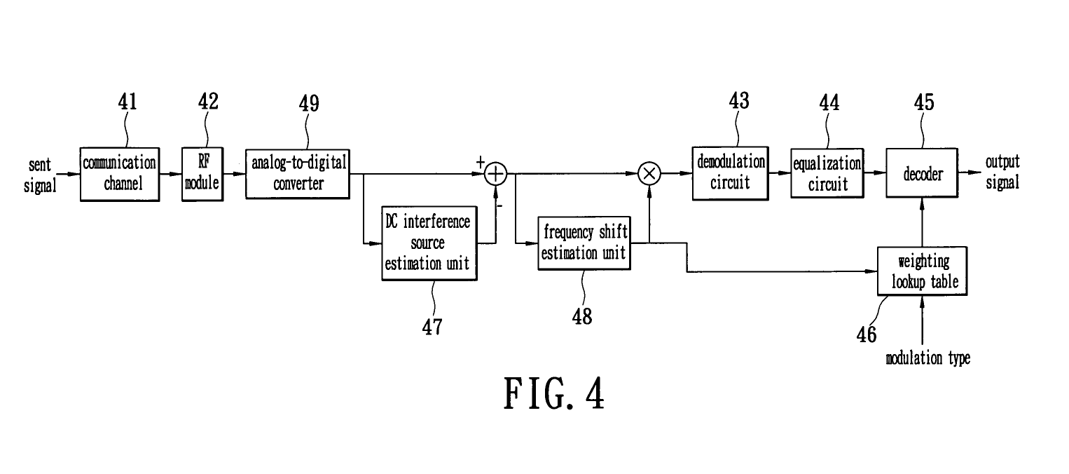

As shown in FIG. 4, during test of an OFDM system, an OFDM signal from the sending end 40 in FIG. 3 is sent to the nearby RF module 42 via the channel 41, and is then converted by the ADC 49. Because the DC source effect generated by the RF module 42 will interfere the OFDM system, a DC interference source estimation unit 47 electrically connected with the RF module 42 can be disposed for eliminating the DC source effect in the present invention. According to an embodiment of the present invention, the signal received by the RF module 42 is filtered by a low-pass filter to filter out high-frequency interference part. Next, several interference signals are averaged by an average unit to obtain an estimation of the DC interference. After elimination of the DC interference, a frequency offset 48 is used to perform compensation of frequency offset to the received signal. A weighting look-up table 46 is then made based on the correspondence between the frequency offset and the modulation type. When the sub-carriers of the channel are processed by the equalization circuit 44 and then enter the decoder 45 for decoding, different weights are given to interfered sub-carriers according to the weighting look-up table 46.

The above modulation type is a transmission way like quadrant amplitude modulation (QAM). Various signal types have different resisting capabilities for noise from the environment or component. The type information can be known from the header of the OFDM signal. In the present invention, when designing the weighting look-up table, different weights are given according to different modulation types and frequency offsets. In practical operation of an OFDM system, different weights are given to interfered sub-carriers according to this weighting look-up table (made through simulation beforehand) during decoding.

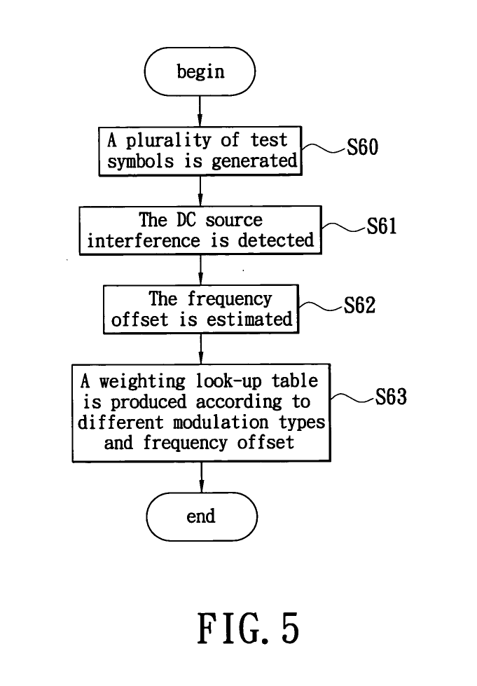

As shown in FIG. 5, the RF module at the receiving end of the OFDM system receives a signal from the sending end. During generation of the weighting look-up table, the RF module in the OFDM system can generate a plurality of test symbols (Step S60). The DC interference source is then detected (Step S61). Frequency offset of the RF module to the OFDM system is then estimated (Step S62). Next, a weighting look-up table is produced according to different modulation types and frequency offset (Step S63). Finally, different weights are given to interfered sub-carriers to accomplish the object of resisting DC interference.

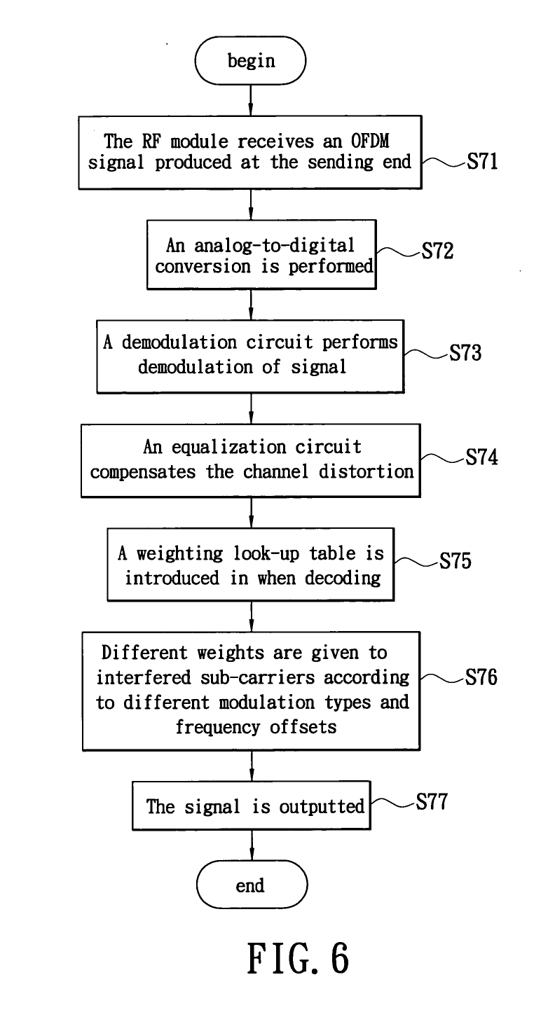

FIG. 6 is a flowchart of a method for resisting DC interference of an OFDM system of the present invention. First, the RF module of the OFDM system receives an OFDM signal (a multi-carrier signal) produced at the sending end (Step S71). A converter then converts the received analog signal into a digital signal (Step S72). Next, a demodulation circuit realized by a discrete Fourier transform circuit performs demodulation of signal (Step S73). An equalization circuit then compensates the channel distortion (Step S74). When the signal enters a decoder, a pre-made weighting look-up table is introduced in (Step S75). Different weights are then given to interfered sub-carriers according to different modulation types and frequency offsets (Step S76). Finally, signals with weighting effect are decoded out (Step S77). Through the above steps, reliable signals with higher weights can protect unreliable signals with lower weights to accomplish the objects of the present invention.

To sum up, the present invention provides a method and device for resisting DC interference of an OFDM system. A weighting look-up table is proposed for the DC source effect generated by the RF component. Different weights are given to interfered sub-carriers according to different modulation types and frequency offsets so that reliable signals can protect unreliable signals to accomplish the object of resisting DC interference.

Although the present invention has been described with reference to the preferred embodiment thereof, it will be understood that the invention is not limited to the details thereof. Various substitutions and modifications have been suggested in the foregoing description, and other will occur to those of ordinary skill in the art. Therefore, all such substitutions and modifications are intended to be embraced within the scope of the invention as defined in the appended claims.

I claim:

1. A method for resisting DC interference of an OFDM system comprising at
least the steps of:
receiving an OFDM signal by using an RF module;
demodulating said OFDM signal by using a demodulation circuit;
introducing in a weighting look-up table;
giving different weight to interfered sub-carriers according to a modulation type and a frequency offset by looking up said weighting look-up table; and
decoding out signals with weighting effect.

2. The method for resisting DC interference of an OFDM system as claimed in claim 1, wherein said frequency offset is produced by the difference between oscillation frequencies at a sending end and a receiving end of said OFDM system.

3. The method for resisting DC interference of an OFDM system as claimed in claim 1, wherein said demodulation circuit is realized by a discrete Fourier transform circuit.

4. The method for resisting DC interference of an OFDM system as claimed in claim 1, wherein said modulation type is known through a header message of said OFDM signal.

5. The method for resisting DC interference of an OFDM system as claimed in claim 1, wherein said weighting look-up table is made beforehand by the steps of:
generating a plurality of multi-carrier test symbols by using said RF module in said OFDM system;
receiving said test symbols from a sending end of said OFDM system by using said RF module at a receiving end of said OFDM system;
estimating a frequency offset; and
producing said weighting look-up table based on modulation type of said signal and said frequency offset.

6. The method for resisting DC interference of an OFDM system as claimed in claim 5, wherein a DC interference estimation unit electrically connected with said RF module is used to estimate DC interference of said RF module to said OFDM system after said step of receiving said test symbols from a sending end of said OFDM system.

7. The method for resisting DC interference of an OFDM system as claimed in claim 5, wherein said step of estimating a frequency offset is accomplished by using a frequency offset estimation unit electrically connected with said demodulation circuit.

8. A device for resisting DC interference of an OFDM system at least comprising:
an RF module for receiving an OFDM signal via a communication channel;
a DC interference estimation unit electrically connected with said RF module for receiving a DC source generated by said RF module;
a demodulation circuit electrically connected with said RF module;
a frequency offset estimation unit electrically connected with said demodulation circuit for getting an estimated frequency offset for said DC source and then obtaining a weighting look-up table based on the correspondence between said frequency offset and a modulation type; and
a decoder electrically connected with said demodulation circuit for giving different weights to interfered sub-carriers according to said weighting look-up table and then decoding for output.

9. The device for resisting DC interference of an OFDM system as claimed in claim 8, wherein said DC interference estimation unit can be accomplished by connecting a low-pass filter with an average operation unit.

10. The device for resisting DC interference of an OFDM system as claimed in claim 8, wherein said demodulation circuit is realized by a discrete Fourier transform circuit.
